(19) United States
(12) Patent Application Publication
(10) Pub. No.: US 2024/0339503 A1
(43) Pub. Date: Oct. 10, 2024

(54) Epitaxial wafer, Method of manufacturing the epitaxial wafer, and Method of manufacturing a semiconductor device using the epitaxial wafer

(71) Applicant: UIF (University Industry Foundation), Yonsei University, Seoul (KR)

(72) Inventors: Dae Hong KO, Goyang-si (KR); Chung Hee CHO, Hwaseong-si (KR); Ki Seok LEE, Seoul (KR); Dong Min YOON, Seoul (KR)

(73) Assignee: UIF (University Industry Foundation), Yonsei University, Seoul (KR)

(21) Appl. No.: 18/624,483

(22) Filed: Apr. 2, 2024

(30) Foreign Application Priority Data
Apr. 5, 2023 (KR) 10-2023-0044761

(51) Int. Cl. H01L 29/165; H01L 21/225; H01L 21/308

(52) U.S. Cl. CPC H01L 29/165; H01L 21/2251; H01L 21/308

(57) ABSTRACT

An epitaxial wafer is disclosed. The epitaxial wafer includes a substrate; and a stack structure disposed on the substrate, wherein the stack structure includes first and second layers alternately stacked on top of each other, wherein the first layer is made of a compound represented by one selected from a group consisting of following Chemical Formulas 1-1 to 1-5, wherein the second layer is made of a compound represented by a following Chemical Formula 2:

Si₁₋ₓGeₓ(m≤x≤1.0) [Chemical Formula 1-1]

Si_{1-x-y}GeₓB_{y}(m≤x<1.0,0<y≤0.4,0.2<x+y≤1.0) [Chemical Formula 1-2]

Si_{1-x-z}GeₓP_{z}(m≤x<1.0,0<z≤0.4,0.2<x+z≤1.0) [Chemical Formula 1-3]

Si_{1-x-z}GeₓC_{z}(m≤x<1.0,0<z≤0.4,0.2<x+z≤1.0) [Chemical Formula 1-4]

Si_{1-x-y-z}GeₓB_{y}P_{z}(0.2<x<1.0,0<y≤0.4,0<z≤0.4,0.2<x+y+z≤1.0) [Chemical Formula 1-5]

Si₁₋ₐGeₐ(0<a≤m) [Chemical Formula 2]

### BACKGROUND

### Field

The present disclosure relates to an epitaxial wafer for manufacturing a semiconductor device, a method for manufacturing the same, and a method for manufacturing a semiconductor device using the same.

### Description of Related Art

Recently, demand for improved integration of a memory element and a non-memory element is increasing. Accordingly, scale down to increase the integration is being continuously researched. Thus, a 3D device implemented in various ways are being proposed as a scheme to increase the integration of the device.

In response to this trend, research is being conducted to manufacture a 3D-DRAM element for a 3D-DRAM device. The 3D-DRAM device has a structure in which the 3D-DRAM elements are manufactured in a three-dimensional manner and are stacked in a Z-axis direction. However, in a three-dimensional stack structure, components of layers are different from each other, such that a stress occurs due to a difference between lattice constants of the layers. As a result, a dislocation between constituent atoms of a crystal lattice may occur and a defect such as a stacking fault may occur.

FIG. 7 is a schematic diagram for illustrating a mechanism based on which the defect occurs in a conventional wafer having a silicon layer and a silicon germanium layer used to manufacture the 3D elements.

Referring to FIG. 7, when an epitaxial silicon layer and an epitaxial silicon germanium layer are stacked on top of each other, the defect inevitably occurs therebetween due to a difference between lattice constants of the silicon layer and the silicon germanium layer. Specifically, the lattice constant of silicon is 5.43 Å, while the lattice constant of germanium is 5.66 Å, so that the silicon germanium layer has a larger lattice constant than that of the silicon layer. Therefore, when the silicon germanium layer is grown epitaxially on the silicon layer, the silicon layer is subjected to a tensile force due to the difference between the lattice constants of the silicon layer and the silicon germanium layer, and as a result, strain may occur. Thus, a misfit dislocation may occur at an interface therebetween. In particular, when a silicon/silicon germanium multilayer thin film is needed to improve the integration, and a total thickness of the silicon germanium layer is large, the above problem may occur more frequently. Thus, there is a limitation in forming the stack structure having an ultra-height.

### SUMMARY

A purpose of the present disclosure is to provide an epitaxial wafer in which a first layer which contains a relatively high concentration of germanium (Ge) in a stack structure of first and second layers is doped with boron (B), phosphorus (P), or carbon (C), thereby reducing a lattice mismatch between the first and second layers, and thus reducing a defect that may otherwise occur therebetween.

Another purpose of the present disclosure is to provide a method for manufacturing a semiconductor device using the epitaxial wafer.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

A first aspect of the present disclosure provides an epitaxial wafer comprising: a substrate; and a stack structure disposed on the substrate, wherein the stack structure includes first and second layers alternately stacked on top of each other, wherein the first layer is made of a compound represented by one selected from a group consisting of following Chemical Formulas 1-1 to 1-5, wherein the second layer is made of a compound represented by a following Chemical Formula 2:

Si₁₋ₓGeₓ(m≤x≤1.0) [Chemical Formula 1-1]

Si_{1-x-y}GeₓB_{y}(m≤x<1.0,0<y≤0.4,0.2<x+y≤1.0) [Chemical Formula 1-2]

Si_{1-x-z}GeₓP_{z}(m≤x<1.0,0<z≤0.4,0.2<x+z≤1.0) [Chemical Formula 1-3]

Si_{1-x-z}GeₓC_{z}(m≤x<1.0,0<z≤0.4,0.2<x+z≤1.0) [Chemical Formula 1-4]

Si_{1-x-y-z}GeₓB_{y}P_{z}(0.2<x<1.0,0<y≤0.4,0<z≤0.4,0.2<x+y+z≤1.0) [Chemical Formula 1-5]

Si₁₋ₐGeₐ(0<a≤m) [Chemical Formula 2]

where in each of the Chemical Formulas 1-1 to 1-5 and the Chemical Formula 2, m is a real number in a range of 0 inclusive to 1 inclusive, and x-a is equal to or larger than 0.2.

In some embodiments of the epitaxial wafer, the first layer is made of a compound represented by one selected from a group consisting of the Chemical Formulas 1-2 to 1-5.

In some embodiments of the epitaxial wafer, an average thickness of each of the first layer and the second layer is in a range of 0 nm exclusive to 200 nm inclusive.

In some embodiments of the epitaxial wafer, the stack structure further includes a third layer disposed between the first layer and the second layer, wherein the third layers acts as a diffusion barrier against diffusion of germanium (Ge).

In some embodiments of the epitaxial wafer, the third layer is made of silicon (Si) doped with arsenic (As) or stibium (Sb).

In some embodiments of the epitaxial wafer, a concentration of arsenic (As) or stibium (Sb) in the third layer is in a range of 0.05 to 10 atomic %.

In some embodiments of the epitaxial wafer, the epitaxial wafer further comprises a buffer layer disposed between the substrate and the stack structure, wherein the buffer layer is made of silicon (Si) doped with germanium (Ge) at a higher doping concentration than a doping concentration at which the first layer is doped with germanium (Ge).

In some embodiments of the epitaxial wafer, the germanium concentration in the buffer layer is in a range of 0.01 to 20 atomic %.

A second aspect of the present disclosure provides a method for manufacturing a semiconductor device, the method comprising: forming a stack structure on a substrate by alternately stacking first and second layers on top of each other on the substrate; forming a first opening exposing at least one first side surface of each of the first and second layers of the stack structure; doping phosphorus (P) into the first side surface of the second layer exposed through the first opening via a thermal diffusion process using a phosphorus (P) source gas, thereby forming a first electrode; forming a second opening exposing at least one second side surface of each of the first and second layers at a position spaced apart from the first opening;
selectively etching the at least one second layer within the second opening to form a semiconductor pattern such that the first electrode is formed on a side surface of the semiconductor pattern; and doping phosphorus (P) into the side surface of the semiconductor pattern exposed through the second opening via a thermal diffusion process using a phosphorus (P) source gas, thereby forming a second electrode, wherein a portion of the second layer remaining between the first electrode and the second electrode functions as a semiconductor channel, wherein the first layer is made of a compound represented by one selected from a group consisting of following Chemical Formulas 1-1 to 1-5,
wherein the second layer is made of a compound represented by a following Chemical Formula 2:

Si₁₋ₓGeₓ(m≤x≤1.0) [Chemical Formula 1-1]

Si_{1-x-y}GeₓB_{y}(m≤x<1.0,0<y≤0.4,0.2<x+y≤1.0) [Chemical Formula 1-2]

Si_{1-x-z}GeₓP_{z}(m≤x<1.0,0<z≤0.4,0.2<x+z≤1.0) [Chemical Formula 1-3]

Si_{1-x-z}GeₓC_{z}(m≤x<1.0,0<z≤0.4,0.2<x+z≤1.0) [Chemical Formula 1-4]

Si_{1-x-y-z}GeₓB_{y}P_{z}(0.2<x<1.0,0<y≤0.4,0<z≤0.4,0.2<x+y+z≤1.0) [Chemical Formula 1-5]

Si₁₋ₐGeₐ(0<a≤m) [Chemical Formula 2]

where in each of the Chemical Formulas 1-1 to 1-5 and the Chemical Formula 2, m is a real number in a range of 0 inclusive to 1 inclusive, and x-a is equal to or larger than 0.2.

In some embodiments of the method, m may be a real number in a range of 0 exclusive to 1 inclusive.

According to the epitaxial wafer of the present disclosure, doping the boron (B), phosphorus (P), or carbon (C) into the first layer containing the relatively high concentration of germanium (Ge) in the stack structure may allow the lattice mismatch between the first layer and the second layer to be reduced. In addition, forming the buffer layer on the substrate and then forming the stack structure thereon may allow the stress generated inside the stack structure due to the lattice mismatch between the first layer and the second layer to be reduced. Further, a difference between the germanium contents of the first layer and the second layer may be maintained at a relatively high level. Thus, the etching selectivity between the first layer and the second layer may be increased.

In addition to the effects as described above, specific effects in accordance with the present disclosure will be described together with following detailed descriptions for carrying out the disclosure.

### BRIEF DESCRIPTION OF DRAWINGS

FIG. 1 is a cross-sectional view for illustrating an epitaxial wafer according to an embodiment of the present disclosure.

FIG. 2 is a cross-sectional view for illustrating an epitaxial wafer according to another embodiment of the present disclosure.

FIGS. 3A to 3C is a graph showing a lattice constant of each of (FIG. 3A) Si_{1-y}B_{y}, (FIG. 3B) Si_{1-y}Al_{y}, and (FIG. 3C) Si_{1-y}Ga_{y} as calculated using LDA and GGA-PBE.

FIG. 4 is a graph showing an average bond length based on a doping concentration of each of Si_{1-y}B_{y}, Si_{1-y}Al_{y}, and Si_{1-y}Ga_{y}.

FIG. 5A is a graph showing a lattice constant based on a change in a concentration of each of Ge and B in Si_{1-x-y}GeₓB_{y}.

FIG. 5B is a graph showing a lattice constant based on a change in a concentration of each of Ge and C in Si_{1-x-y}GeₓC_{y}.

FIGS. 6A to 6C show Ge and B compositions and strain and defect analysis results measured on an epitaxial wafer according to each of Comparative Example and Present Example, respectively. FIGS. 6D to 6F show strain and defect analysis results measured on an epitaxial wafer according to each of Comparative Examples 1 and 2 and Present Example, respectively.

FIG. 7 is a schematic diagram for illustrating the mechanism based on which the defect occurs in the prior art.

FIG. 8 is a circuit diagram of a cell of a memory element according to an embodiment of the present disclosure.

FIG. 9 to FIG. 21 are process charts for illustrating a manufacturing process of a memory element.

FIG. 22 is a perspective view schematically showing an epitaxial wafer according to an embodiment of the present disclosure.

FIG. 23 is a plan view of FIG. 22.

FIG. 24 is a cross-sectional view showing an I-l′ area in FIG. 22.

FIG. 25 is a cross-sectional view showing an II-II″ area of FIG. 22.

### DETAILED DESCRIPTIONS

Advantages and features of the present disclosure, and a method of achieving the advantages and features will become apparent with reference to embodiments described later in detail together with the accompanying drawings. However, an embodiment of embodiments of the present disclosure are not limited to the embodiments as disclosed under, but may be implemented in various different forms. Thus, these embodiments are set forth only to make the present disclosure complete, and to entirely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims.

A shape, a size, a ratio, an angle, a number, etc. disclosed in the drawings for illustrating embodiments of the present disclosure are illustrative, and an embodiment of embodiments of the present disclosure are not limited thereto.

The terminology used herein is directed to the purpose of describing particular embodiments only and is not intended to be limiting of the present disclosure. As used herein, the singular constitutes “a” and “an” are intended to include the plural constitutes as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of associated listed items. Expression such as “at least one of” when preceding a list of elements may modify the entire list of elements and may not modify the individual elements of the list. In interpretation of numerical values, an error or tolerance therein may occur even when there is no explicit description thereof.

It will also be understood that when a first element or layer is referred to as being present “on” a second element or layer, the first element may be disposed directly on the second element or may be disposed indirectly on the second element with a third element or layer being disposed between the first and second elements or layers. It will also be understood that when a first element or layer is referred to as being present “under” a second element or layer, the first element may be disposed directly under the second element or may be disposed indirectly under the second element with a third element or layer being disposed between the first and second elements or layers.

It will be understood that when an element or layer is referred to as being “connected to”, or “coupled to” another element or layer, it may be directly connected to or coupled to another element or layer, or one or more intervening elements or layers therebetween may be present. In addition, it will also be understood that when an element or layer is referred to as being “between” two elements or layers, it may be the only element or layer between the two elements or layers, or one or more intervening elements or layers therebetween may also be present.

In addition, it will also be understood that when an element or layer is referred to as being “between” two elements or layers, it may be the only element or layer between the two elements or layers, or one or more intervening elements or layers therebetween may also be present.

Further, as used herein, when a layer, film, region, plate, or the like is disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like is disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain embodiment may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

The features of the various embodiments of the present disclosure may be partially or entirely combined with each other, and may be technically associated with each other or operate with each other. The embodiments may be implemented independently of each other and may be implemented together in an association relationship.

In interpreting a numerical value, the value is interpreted as including an error range unless there is no separate explicit description thereof.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

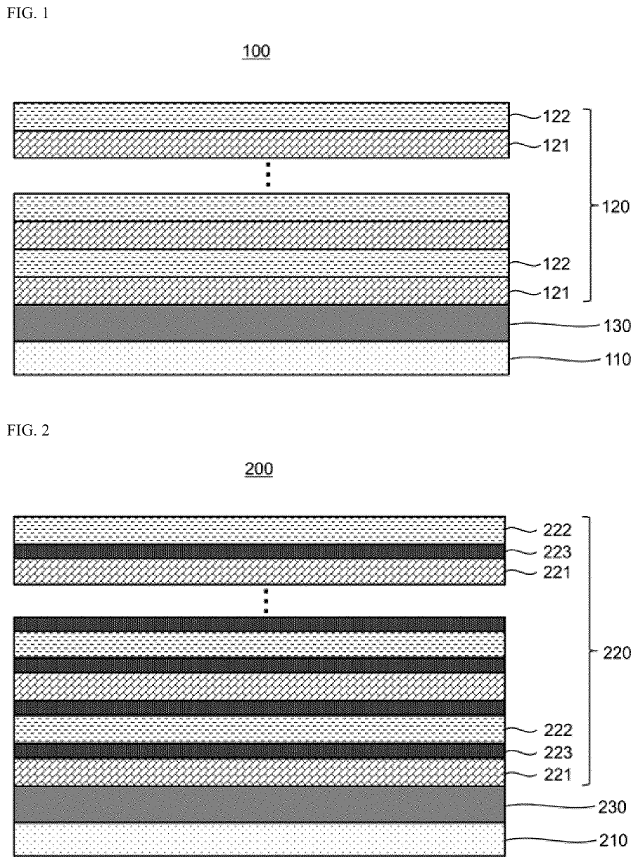

FIG. 1 is a cross-sectional view for illustrating an epitaxial wafer according to an embodiment of the present disclosure.

Referring to FIG. 1, an epitaxial wafer 100 according to an embodiment of the present disclosure includes a substrate 110; a stack structure 120; and a buffer layer 130.

The substrate 110 is not particularly limited, and may include a known substrate for a semiconductor device without limitation thereto. In one embodiment, the substrate 110 may include a silicon wafer with an insulating film formed in a surface thereof, such as a SOI (Silicon on Insulator).

The stack structure 120 may be disposed on the substrate 110 and may have a structure in which two or more different layers are alternately stacked on top of each other.

In one embodiment, the stack structure 120 may include first layers 121 and second layers 122 that are alternately stacked on top of each other and have different etching characteristics. In this case, the first layer 121 may act as the lowest layer of the stack structure 120, so that the first layer 121 may be disposed adjacent to the substrate 110. Alternatively, the second layer 122 may act as the lowest layer of the stack structure 120, such that the second layer 122 may be disposed adjacent to the substrate 110.

In one embodiment, the first layer 121 may be made of a compound represented by one selected from a group consisting of following Chemical Formula 1-1 to Chemical Formula 1-5, and the second layer 122 may be made of a compound represented by a following Chemical Formula 2. The first layer 121 and the second layer 122 may contact each other. Since a concentration of a germanium element contained in the first layer 121 is higher than a concentration of a germanium element contained in the second layer 122, the first layer 121 and the second layer 122 may have different etching characteristics. Thus, only one of the first layer 121 and the second layer 122 may be selectively etched. In one embodiment, a difference between the concentration of the germanium element contained in the first layer 121 and the concentration of the germanium element contained in the second layer 122 may be in a range of 20 atomic % or greater:

Si₁₋ₓGeₓ(m≤x≤1.0) [Chemical Formula 1-1]

Si_{1-x-y}GeₓB_{y}(m≤x<1.0,0<y≤0.4,0.2<x+y≤1.0) [Chemical Formula 1-2]

Si_{1-x-z}GeₓP_{z}(m≤x<1.0,0<z≤0.4,0.2<x+z≤1.0) [Chemical Formula 1-3]

Si_{1-x-z}GeₓC_{z}(m≤x<1.0,0<z≤0.4,0.2<x+z≤1.0) [Chemical Formula 1-4]

Si_{1-x-y-z}GeₓB_{y}P_{z}(0.2<x<1.0,0<y≤0.4,0<z≤0.4,0.2<x+y+z≤1.0) [Chemical Formula 1-5]

Si₁₋ₐGeₐ(0<a≤m) [Chemical Formula 2]

In one embodiment, in the Chemical Formulas 1-1 to 1-5 and the Chemical Formula 2, m may be a real number in a range of 0 inclusive to 1 inclusive. In one embodiment, m may be a real number in a range of 0 exclusive to 1 inclusive. In the Chemical Formulas 1-2 to 1-5, a ratio (y/x) of y to x may be in a range of about 0.01 to 0.5, for example, about 0.06 to 0.15. y may be greater than or equal to z.

The value of y is not specifically limited. In one embodiment, The y can be from 0 to 0.025, from 0 to 0.05, from 0 to 0.075, from 0 to 0.1, from 0 to 0.125, from 0 to 0.15, from 0 to 0.175, from 0 to 0.2, from 0 to 0.225, from 0 to 0.25, from 0 to 0.275, from 0 to 0.3, from 0 to 0.325, from 0 to 0.35, from 0 to 0.375, from 0 to 0.4, from 0.025 to 0.05, from 0.025 to 0.075, from 0.025 to 0.1, from 0.025 to 0.125, from 0.025 to 0.15, from 0.025 to 0.175, from 0.025 to 0.2, from 0.025 to 0.225, from 0.025 to 0.25, from 0.025 to 0.275, from 0.025 to 0.3, from 0.025 to 0.325, from 0.025 to 0.35, from 0.025 to 0.375, from 0.025 to 0.4, from 0.05 to 0.075, from 0.05 to 0.1, from 0.05 to 0.125, from 0.05 to 0.15, from 0.05 to 0.175, from 0.05 to 0.2, from 0.05 to 0.225, from 0.05 to 0.25, from 0.05 to 0.275, from 0.05 to 0.3, from 0.05 to 0.325, from 0.05 to 0.35, from 0.05 to 0.375, from 0.05 to 0.4, from 0.075 to 0.1, from 0.075 to 0.125, from 0.075 to 0.15, from 0.075 to 0.175, from 0.075 to 0.2, from 0.075 to 0.225, from 0.075 to 0.25, from 0.075 to 0.275, from 0.075 to 0.3, from 0.075 to 0.325, from 0.075 to 0.35, from 0.075 to 0.375, from 0.075 to 0.4, from 0.1 to 0.125, from 0.1 to 0.15, from 0.1 to 0.175, from 0.1 to 0.2, from 0.1 to 0.225, from 0.1 to 0.25, from 0.1 to 0.275, from 0.1 to 0.3, from 0.1 to 0.325, from 0.1 to 0.35, from 0.1 to 0.375, from 0.1 to 0.4, from 0.125 to 0.15, from 0.125 to 0.175, from 0.125 to 0.2, from 0.125 to 0.225, from 0.125 to 0.25, from 0.125 to 0.275, from 0.125 to 0.3, from 0.125 to 0.325, from 0.125 to 0.35, from 0.125 to 0.375, from 0.125 to 0.4, from 0.15 to 0.175, from 0.15 to 0.2, from 0.15 to 0.225, from 0.15 to 0.25, from 0.15 to 0.275, from 0.15 to 0.3, from 0.15 to 0.325, from 0.15 to 0.35, from 0.15 to 0.375, from 0.15 to 0.4, from 0.175 to 0.2, from 0.175 to 0.225, from 0.175 to 0.25, from 0.175 to 0.275, from 0.175 to 0.3, from 0.175 to 0.325, from 0.175 to 0.35, from 0.175 to 0.375, from 0.175 to 0.4, from 0.2 to 0.225, from 0.2 to 0.25, from 0.2 to 0.275, from 0.2 to 0.3, from 0.2 to 0.325, from 0.2 to 0.35, from 0.2 to 0.375, from 0.2 to 0.4, from 0.225 to 0.25, from 0.225 to 0.275, from 0.225 to 0.3, from 0.225 to 0.325, from 0.225 to 0.35, from 0.225 to 0.375, from 0.225 to 0.4, from 0.25 to 0.275, from 0.25 to 0.3, from 0.25 to 0.325, from 0.25 to 0.35, from 0.25 to 0.375, from 0.25 to 0.4, from 0.275 to 0.3, from 0.275 to 0.325, from 0.275 to 0.35, from 0.275 to 0.375, from 0.275 to 0.4, from 0.3 to 0.325, from 0.3 to 0.35, from 0.3 to 0.375, from 0.3 to 0.4, from 0.325 to 0.35, from 0.325 to 0.375, from 0.325 to 0.4, from 0.35 to 0.375, from 0.35 to 0.4, or from 0.375 to 0.4.

The value of z is not specifically limited. In one embodiment, The z can be from 0 to 0.025, from 0 to 0.05, from 0 to 0.075, from 0 to 0.1, from 0 to 0.125, from 0 to 0.15, from 0 to 0.175, from 0 to 0.2, from 0 to 0.225, from 0 to 0.25, from 0 to 0.275, from 0 to 0.3, from 0 to 0.325, from 0 to 0.35, from 0 to 0.375, from 0 to 0.4, from 0.025 to 0.05, from 0.025 to 0.075, from 0.025 to 0.1, from 0.025 to 0.125, from 0.025 to 0.15, from 0.025 to 0.175, from 0.025 to 0.2, from 0.025 to 0.225, from 0.025 to 0.25, from 0.025 to 0.275, from 0.025 to 0.3, from 0.025 to 0.325, from 0.025 to 0.35, from 0.025 to 0.375, from 0.025 to 0.4, from 0.05 to 0.075, from 0.05 to 0.1, from 0.05 to 0.125, from 0.05 to 0.15, from 0.05 to 0.175, from 0.05 to 0.2, from 0.05 to 0.225, from 0.05 to 0.25, from 0.05 to 0.275, from 0.05 to 0.3, from 0.05 to 0.325, from 0.05 to 0.35, from 0.05 to 0.375, from 0.05 to 0.4, from 0.075 to 0.1, from 0.075 to 0.125, from 0.075 to 0.15, from 0.075 to 0.175, from 0.075 to 0.2, from 0.075 to 0.225, from 0.075 to 0.25, from 0.075 to 0.275, from 0.075 to 0.3, from 0.075 to 0.325, from 0.075 to 0.35, from 0.075 to 0.375, from 0.075 to 0.4, from 0.1 to 0.125, from 0.1 to 0.15, from 0.1 to 0.175, from 0.1 to 0.2, from 0.1 to 0.225, from 0.1 to 0.25, from 0.1 to 0.275, from 0.1 to 0.3, from 0.1 to 0.325, from 0.1 to 0.35, from 0.1 to 0.375, from 0.1 to 0.4, from 0.125 to 0.15, from 0.125 to 0.175, from 0.125 to 0.2, from 0.125 to 0.225, from 0.125 to 0.25, from 0.125 to 0.275, from 0.125 to 0.3, from 0.125 to 0.325, from 0.125 to 0.35, from 0.125 to 0.375, from 0.125 to 0.4, from 0.15 to 0.175, from 0.15 to 0.2, from 0.15 to 0.225, from 0.15 to 0.25, from 0.15 to 0.275, from 0.15 to 0.3, from 0.15 to 0.325, from 0.15 to 0.35, from 0.15 to 0.375, from 0.15 to 0.4, from 0.175 to 0.2, from 0.175 to 0.225, from 0.175 to 0.25, from 0.175 to 0.275, from 0.175 to 0.3, from 0.175 to 0.325, from 0.175 to 0.35, from 0.175 to 0.375, from 0.175 to 0.4, from 0.2 to 0.225, from 0.2 to 0.25, from 0.2 to 0.275, from 0.2 to 0.3, from 0.2 to 0.325, from 0.2 to 0.35, from 0.2 to 0.375, from 0.2 to 0.4, from 0.225 to 0.25, from 0.225 to 0.275, from 0.225 to 0.3, from 0.225 to 0.325, from 0.225 to 0.35, from 0.225 to 0.375, from 0.225 to 0.4, from 0.25 to 0.275, from 0.25 to 0.3, from 0.25 to 0.325, from 0.25 to 0.35, from 0.25 to 0.375, from 0.25 to 0.4, from 0.275 to 0.3, from 0.275 to 0.325, from 0.275 to 0.35, from 0.275 to 0.375, from 0.275 to 0.4, from 0.3 to 0.325, from 0.3 to 0.35, from 0.3 to 0.375, from 0.3 to 0.4, from 0.325 to 0.35, from 0.325 to 0.375, from 0.325 to 0.4, from 0.35 to 0.375, from 0.35 to 0.4, or from 0.375 to 0.4.

In one embodiment, each of the first layer 121 and the second layer 122 may be formed epitaxially using a chemical vapor deposition (CVD) scheme.

In one example, the first layer 121 made of the compound represented by the Chemical Formula 1-1 may be formed by supplying a silicon (Si) source gas and a germanium (Ge) source gas into a chamber at a temperature of about 400 to 700° C. in which the substrate 110 is received to deposit silicon (Si) and germanium (Ge) thereon. In this regard, a known compound applicable to a semiconductor process may be used as each of the silicon source gas and the germanium source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. In one example, a supply amount and a pressure of each of the source gases may be controlled such that a composition of the compound represented by the Chemical Formula 1-1 may be adjusted.

In another example, the first layer 121 made of the compound represented by the Chemical Formula 1-2 may be formed by supplying a silicon (Si) source gas, a germanium (Ge) source gas, and a boron (B) source gas into a chamber at a temperature of about 400 to 700° C. in which the substrate 110 is received to deposit silicon (Si), germanium (Ge), and boron (B) thereon. In this regard, a known compound applicable to a semiconductor process may be used as each of the silicon source gas, the germanium source gas, and the boron source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. Diborane (B₂H₆), etc. may be used as the boron source gas. In one example, a supply amount and a pressure of each of the source gases may be controlled such that a composition of the compound represented by the Chemical Formula 1-2 may be adjusted.

In still another example, the first layer 121 made of the compound represented by the Chemical Formula 1-3 may be formed by supplying a silicon (Si) source gas, a germanium (Ge) source gas, and a phosphorus (P) source gas into a chamber at a temperature of about 400 to 700° C. in which the substrate 110 is received to deposit silicon (Si), germanium (Ge), and phosphorus (P) thereon. In this regard, a known compound applicable to a semiconductor process may be used as each of the silicon source gas, the germanium source gas, and the phosphorus source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. Phosphine (PH₃), etc. may be used as the phosphorus source gas. In one example, a supply amount and a pressure of each of the source gases may be controlled such that a composition of the compound represented by the Chemical Formula 1-3 may be adjusted.

In still yet another example, the first layer 121 made of the compound represented by the Chemical Formula 1-4 may be formed by supplying a silicon (Si) source gas, a germanium (Ge) source gas, and a carbon (C) source gas into a chamber at a temperature of about 400 to 700° C. in which the substrate 110 is received to deposit silicon (Si), germanium (Ge), and carbon (C) thereon. In this regard, a known compound applicable to a semiconductor process may be used as each of the silicon source gas, the germanium source gas, and the carbon source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. Dichlorosilane (SiH₂Cl₂), trichlorosilane (SiCl₃H), etc. may be used as the carbon source gas. In one example, a supply amount and a pressure of each of the source gases may be controlled such that a composition of the compound represented by the Chemical Formula 1-4 may be adjusted.

In still yet another example, the first layer 121 made of the compound represented by the Chemical Formula 1-5 may be formed by supplying a silicon (Si) source gas, a germanium (Ge) source gas, a boron (B) source gas, and a phosphorus (P) source gas into a chamber at a temperature of about 400 to 700° C. in which the substrate 110 is received to deposit silicon (Si), germanium (Ge), boron (B), and phosphorus (P) thereon. In this regard, a known compound applicable to a semiconductor process may be used as each of the silicon source gas, the germanium source gas, the boron source gas, and the phosphorus source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. Diborane (B₂H₆), etc. may be used as the boron source gas. Phosphine (PH₃), etc. may be used as the phosphorus source gas. In one example, a supply amount and a pressure of each of the source gases may be controlled such that a composition of the compound represented by the Chemical Formula 1-5 may be adjusted.

In one example, the second layer 122 made of the compound represented by the Chemical Formula 2 may be formed by supplying a silicon (Si) source gas and a germanium (Ge) source gas into a chamber at a temperature of about 400 to 700° C. in which the substrate 110 is received to deposit silicon (Si) and germanium (Ge) thereon. In this regard, a known compound applicable to a semiconductor process may be used as each of the silicon source gas and the germanium source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Germane (GeH₄) or the like may be used as the germanium source gas. In one example, a supply amount and a pressure of each of the source gases may be controlled such that a composition of the compound represented by the Chemical Formula 2 may be adjusted.

In one embodiment, a thickness of each of the first layer 121 and the second layer 122 may not be particularly limited. For example, an average thickness of each of the first layer 121 and the second layer 122 may be in a range of about 200 nm or smaller, for example, about 5 to 100 nm.

In one embodiment, the stack structure 120 may include the first layer 121 of the thickness in a range of about 2 to 1000 nm and the second layer 122 of the thickness in a range of about 2 to 1000 nm.

The buffer layer 130 may be disposed between the substrate 110 and the stack structure 120, such that stress generated in the stack structure 120 due to a lattice mismatch between the first layer 121 and the second layer 122 may be reduced. In one embodiment, the buffer layer 130 may be made of silicon germanium represented by a following Chemical Formula 3, where a concentration of germanium (Ge) thereof is lower than that of the first layer 121 and is higher than that of the second layer 122. In this regard, the buffer layer 130 may be thicker than each of the first layer 121 and the second layer 122.

Si₁₋ₙGeₙ(a<n<x) [Chemical Formula 3]

In one example, the buffer layer 130 may be in contact with the first layer 121 or the second layer 122 as the lowest layer of the stack structure 120 and may have a thickness in a range of about 10 μm or smaller, preferably about 0.3 to 5 μm.

FIG. 2 is a cross-sectional view for illustrating an epitaxial wafer according to another embodiment of the present disclosure.

Referring to FIG. 2, an epitaxial wafer 200 according to another embodiment of the present disclosure includes a substrate 210; a stack structure 220; and a buffer layer 230.

Since the substrate 210 and the buffer layer 230 are substantially the same as the substrate 110 and the buffer layer 130 of the epitaxial wafer 100 as described above with reference to FIG. 1, respectively, duplicate detailed descriptions thereof will be omitted.

The stack structure 220 may include first and second layers 221 and 222 alternately stacked on top of each other and having different etching characteristics; and a third layer 223 disposed between the first layer 221 and the second layer 222 adjacent to each other and acting as a diffusion barrier against diffusion of germanium (Ge).

The first layer 221 and the second layer 222 are substantially the same as the first layer 121 and the second layer 122 of the stack structure 120 of the epitaxial wafer 100 as described above with reference to FIG. 1, respectively. Thus, duplicate detailed descriptions thereof will be omitted.

The third layer 223 may be made of silicon (Si) doped with arsenic (As) or stibium (Sb). The arsenic (As) or stibium (Sb) has a covalent bond radius larger than that of germanium (Ge) and a diffusivity that is smaller than that of germanium (Ge). Thus, the arsenic (As) or stibium (Sb) may prevent thermal diffusion of the germanium (Ge) element from the first layer 221 doped with germanium at a relatively high concentration to the second layer 222 doped with germanium at a relatively low concentration during the deposition of one of the first layer 221 and the second layer 222. As a result, a difference between compositions of the first layers 221 and a difference between compositions of between the second layers 222 may be reduced. Etching characteristics may vary depending on the composition. Thus, when the first layers 221 have different compositions or the second layers 222 have different compositions, etch profiles of the first layers 221b may be different from each other or etch profiles of the second layers 222 may be different from each other even when etching is performed using the same etchant under the same condition. However, when the third layer 223 that acts as the diffusion barrier is disposed between the first layer 221 and the second layer 222, the first layers 221 have uniform compositions regardless of their positions and the second layers 222b may have uniform compositions regardless of their positions, such that etching non-uniformity that may occur due to the composition difference may be significantly reduced.

The third layer 223 may be formed epitaxially using a chemical vapor deposition (CVD) scheme.

In one embodiment, the third layer 223 may be formed by supplying a silicon (Si) source gas, and an arsenic (As) or stibium (Sb) source gas into a chamber at a temperature of about 400 to 700° C. in which the substrate 110 on which the first layer 221 or the second layer 222 has been formed is received to deposit silicon (Si), and arsenic (As) or stibium (Sb) thereon. In this regard, a known compound applicable to a semiconductor process may be used as each of the silicon source gas, and the arsenic (As) or stibium (Sb) source gas without limitation thereto. For example, nth-order silane (SiₙH₂ₙ₊₂, n=1 to 5), dichlorosilane (SiH₂Cl₂), trichlorosilane (SiCl₃H), etc. may be used as the silicon source gas. Arsine (AsH₃) may be used as the arsenic (As) source gas, and stibine (Sb) H₃) may be used as the stibium (Sb) source gas. In one example, a supply amount and a pressure of each of the source gases may be controlled such that a composition of the third layer 223 may be adjusted.

In one embodiment, in the third layer 223, the arsenic (As) or stibium (Sb) may be doped at a content of about 0.05 to 10 atomic %. When the arsenic (As) or stibium (Sb) is doped at a content smaller than 0.05 atomic %, a problem may occur in which the third layer 123b cannot substantially perform its function as the diffusion barrier against the diffusion of germanium. When the arsenic (As) or stibium (Sb) is doped in excess of 10 atomic %, problems related to epi growth or etch selectivity may occur.

In one embodiment, a thickness of the third layer 223 may be significantly smaller than that of each of the first layer 221 and the second layer 222b. For example, the third layer 223b may be formed to have a thickness of about 0.5 to 5 nm.

According to the epitaxial wafer of the present disclosure, the boron (B) or phosphorus (P) may be doped into the first layer containing a relatively high concentration of germanium (Ge) in the stack structure, thereby reducing the lattice mismatch between the first layer and the second layer. In addition, the buffer layer may be formed on the substrate and then the stack structure may be formed thereon. Thus, the stress generated inside the stack structure due to the lattice mismatch between the first layer and the second layer may be reduced. The difference between the germanium contents of the first layer and the second layer may be maintained at a relatively high level. Thus, the etching selectivity between the first layer and the second layer may be increased.

In one example, the epitaxial wafer 100 or 200 may include a first area located as a middle portion thereof and in which a 3D-semiconductor element is formed, and a second area located as an edge portion surrounding the first area. Thus, the stack structure 120 or 220 located in the first area may be processed through a semiconductor process to manufacture a plurality of semiconductor unit elements.

In one embodiment, in order to manufacture the semiconductor unit element, one of the first layer 121 or 221 and the second layer 122 or 222 of the stack structure 120 or 220 located in the first area, for example, the first layer 121 or 221 containing the relatively high concentration of germanium may be selectively removed in order to form an insulating layer. For example, the insulating layer may include an inner space formed by selectively removing a portion of the first layer 121 or 221, and an insulating material that fills the inner space. In this case, the insulating material may include silicon oxide, silicon nitride, or silicon oxynitride. The plurality of unit elements may be respectively formed in areas distinguished from each other via a scribe line and may be spaced apart from each other. Through a dicing process using the scribe line SL, the unit elements may be separated from each other and cut into individual chips.

In one embodiment, each of the plurality of unit elements may include a cell area CELL including a memory cell array and a circuit area (PERI; peripheral circuit area that controls the memory cell array.

In one embodiment, the unit element included in the first area may include a plurality of word-lines, a plurality of memory cell transistors connected to each word-line, and a plurality of bit-lines connected to the memory cell transistor. This structure may be a structure in which one memory cell transistor is disposed between one word-line and one bit-line. A gate of the memory cell transistor may be connected to the word-line, and a source of the memory cell transistor may be connected to the bit-line. Each memory cell may include a capacitor. The word-line, the memory cell transistor, the bit-line, and the capacitor may constitute one cell, and one unit element may include a plurality of cells.

In one embodiment of the present disclosure, at least two or more of the plurality of memory cell transistors included in each of the plurality of unit elements disposed in the first area of the epitaxial wafer may be arranged in the stacking direction of the layers in the stack structure. This structure may be a structure in which the plurality of memory cell transistors within the unit element are stacked and arranged in a third direction D3. That is, the unit element included in the first area of the epitaxial wafer according to the above example may be a three-dimensional semiconductor memory element.

In one embodiment, the plurality of word-lines included in the unit element may extend in a perpendicular manner to the substrate 110 or 210. Within one unit element, the plurality of word-lines may be arranged to be spaced apart from each other in a first direction D1 or a second direction D2. When the plurality of word-lines extend in a perpendicular manner to the substrate 110 or 210, the plurality of bit-lines included in the unit element may extend in a parallel manner to an upper surface of the substrate 110 or 210, and may be arranged and spaced from each other in the third direction 3D.

In another embodiment, the plurality of bit-lines included in the unit element may extend in a perpendicular manner to the substrate 110 or 210. Within one unit element, the plurality of bit-lines may be arranged to be spaced apart from each other in the first direction D1 or the second direction D2. When the plurality of bit-lines extend in a perpendicular manner to the substrate 110 or 210, the plurality of word-lines included in the unit element may extend in a parallel manner to the upper surface of the substrate 110 or 210, and may be arranged and spaced from each other in the third direction 3D.

In still another embodiment, the plurality of word-lines and the plurality of bit-lines included in the unit element may extend in a perpendicular manner to the substrate 110 or 210. Within one unit element, the plurality of word-lines and the plurality of bit-lines may be arranged to be spaced apart from each other in the first direction D1 or the second direction D2.

The word-line and/or bit-line may be embodied as a conductive pattern and may have a line shape or a bar shape. The word-line and/or the bit-line may include one selected from a conductive material, for example, doped semiconductor material (doped silicon, doped germanium, etc.), conductive metal nitride (titanium nitride, tantalum nitride, etc.), metal (tungsten, titanium, tantalum, etc.), and a metal-semiconductor compound (tungsten silicide, cobalt silicide, titanium silicide, etc.). However, embodiments of the present disclosure are not limited thereto.

A method for manufacturing an epitaxial wafer according to an embodiment of the present disclosure includes forming the buffer layer 130 or 230 on the substrate 110 or 210; and forming the stack structure 120 or 220 on the buffer layer 130 or 230.

Since the method of forming each of the buffer layer 130 or 230 and the stack structure 120 or 220 has already been described above, redundant detailed description thereof will be omitted.

In one embodiment, the method for manufacturing the epitaxial wafer may further include forming an insulating film on the stack structure 120 or 220, if necessary.

In one embodiment, in order to manufacture the unit element, a patterning process may be performed on the stack structure 120 or 220. The patterning process may include forming a mask pattern having openings defined therein, etching the stack structure 120 or 220 using the mask pattern as an etch mask, and removing the mask pattern. Through the patterning process, a trench may be formed in the stack structure 120 or 220, and a portion of an upper surface of the buffer layer 130 or 230 may be exposed through the trench. Afterwards, a process of forming a new insulating film inside the trench may be performed. The new insulating film may have an etch selectivity.

The patterning process may be performed multiple times depending on a structure of the unit element. When performing the patterning process multiple times, a process of forming a new insulating film may be performed after etching at least a portion of the insulating film formed in a previous step.

According to the present disclosure, the semiconductor unit element that has been manufactured after performing the patterning process may be formed in the first area of the epitaxial wafer 100 or 200. The semiconductor unit element may include a stack structure of remaining layers that are not removed in the patterning process among the first layers 121 or 221 and the second layers 122 or 222, and the insulating films newly formed in the areas in from which the first and second layers have been removed in the etching process.

In one example, in the patterning process, a portion of the stack structure 120 or 220 located on the second area of the epitaxial wafer 100 or 200 may be located outside the mask pattern and may remain without being patterned.

In one embodiment, after performing the patterning process, an impurity doping process may be performed on a portion of the semiconductor exposed in the etching process, if necessary. The impurity may be a p-type impurity or an n-type impurity. The p-type impurities may include B, BF, or a combination thereof, and the n-type impurities may include P, As, or a combination thereof.

In one embodiment, after performing the patterning process, a process of converting the semiconductor exposed in the etching process with a conductive material may be performed, if necessary. The process of converting the semiconductor with the conductive material may include, for example, a silicide process. The exposed semiconductor may react with a metal to be converted to a metal-semiconductor compound (tungsten silicide, cobalt silicide, titanium silicide, etc.). In another example, converting the semiconductor into the conductive material may include conformally forming an electrically conductive metal nitride film or metal film on the semiconductor.

In one embodiment, after performing the patterning process, etc., a process of filling an empty space of the remaining trench with an insulating film may be performed, if necessary. The insulating film may include one of a silicon oxide film, a silicon nitride film, and a silicon oxynitride film.

FIG. 8 is a circuit diagram of a cell of a memory element according to an embodiment of the present disclosure, and FIGS. 9 to 21 are process diagrams for illustrating a manufacturing process of the memory element.

Referring to FIG. 8, a cell 1000 of the memory element according to the embodiment of the present disclosure may include an n-type transistor 1100 and a capacitor 1200.

The n-type transistor 1100 may include a drain electrode 1110 electrically connected to the bit-line BL, a source electrode 1120 electrically connected to the capacitor 1200, a channel area formed between the source electrode 1120 and the drain electrode 1110, and a gate electrode 1130 electrically connected to the word-line WL.

In one embodiment, each of the source electrode 11200 and the drain electrode 1110 may be made of n-doped silicon germanium. The channel area may be made of p-doped silicon germanium.

In one embodiment, the gate electrode 1130 may be disposed on top of the channel area. A gate insulating layer may be disposed between the gate electrode 12 and the channel area. The gate electrode 1130 may be made of an electrically conductive material, for example, a metal or a metal-containing material, The gate insulating film may be made of a dielectric having insulating properties.

The capacitor 1200 may include an outer electrode layer 1210 electrically connected to the source electrode 1120, an inner electrode layer 1220 electrically connected to a power supply node such as a ground node, and a dielectric layer disposed therebetween.

In one embodiment, each of the outer electrode layer 1210 and the inner electrode layer 1220 may be made of an electrically conductive material, for example, a metal or a metal-containing material. The dielectric layer may be made of a high-K dielectric material.

Referring to FIGS. 9 to 21, the manufacturing method of the memory element according to an embodiment of the present disclosure may manufacture a pair of memory element cells mirrored with each other along a vertical axis. The drawing shows a process on manufacturing a pair of memory cells. However, the present disclosure is not limited thereto. When the number of stacks of the first and second layers included in the stack structure is increased, a plurality of pairs of memory cells arranged in a deposition direction are manufactured.

Referring to FIG. 9, the first layers 120a and the second layers 110a may be sequentially stacked on top of each other on the substrate 10 to form a stack structure 20 of the first layers 120a and the second layers 110a having the same structure as a first stack structure 120 of the epitaxial wafer 100 as described with reference to FIG. 1. The stack structure 20 may have a structure in which two or more first layers 120a and two or more second layers 110a are alternately stacked on top of each other.

In one embodiment, each of the second layer 110a and the first layer 120a may be formed in chemical vapor deposition in the same chamber. The first layer 120a may be doped with boron (B) or may be doped with boron (B) and phosphorus (P) simultaneously. In this case, during the formation process of the first layer 120a, a trace amount of boron or phosphorus may be doped into the second layer 110a. Since the method of forming the second layer 110a and the first layer 120a has already been described above, redundant detailed description thereof will be omitted.

Referring to FIG. 10, a first opening G1 may be formed that extends through the second layer 110b and the first layer 120b of the stack structure 20. The first opening G1 may be formed through an anisotropic etching process such as reactive ion etching (RIE).

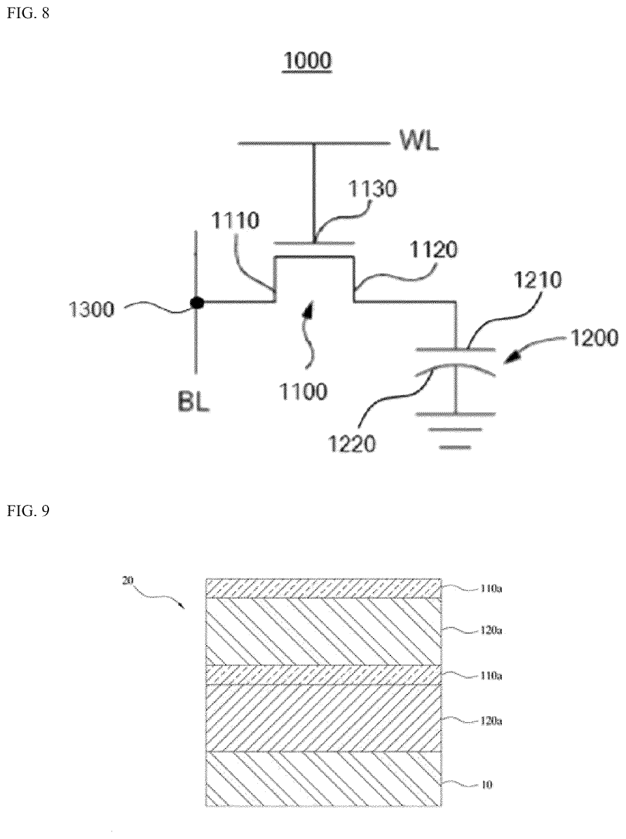

Referring to FIG. 11, a pullback process may be performed on exposed first layers 120c inside the first opening G1, and recesses R1 extending laterally may be formed respectively in the first layers 120c. The pullback process may be performed through a selective, isotropic etching process on the first layers 120c. For example, the pullback process on the first layers 120c may be performed through an etching process using a mixed solution of hydrogen fluoride (HF), hydrogen peroxide (H₂O₂), and acetic acid (CH₃COOH).

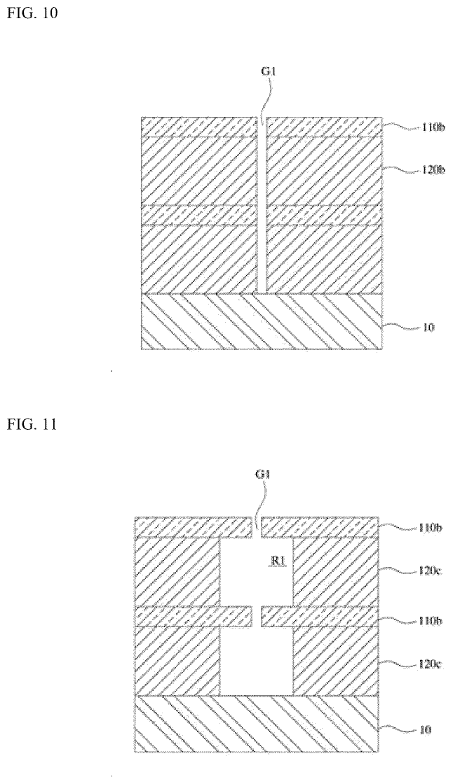

Referring to FIG. 12, an isotropic sacrificial material layer 130a and a dielectric filling material layer 140a may be formed in each of the lateral first recesses R1 of the first layers 120c. The isotropic sacrificial material 130a may be formed through an isotropic deposition process such as an atomic layer deposition (ALD) process. In this regard, the isotropic sacrificial material layer 130a may be formed to a certain thickness and along upper and lower surfaces of the vertically adjacent second layers 110b and side surfaces of the pulled back first layers 120c located therebetween, such that a groove corresponding to the first recess R1 of the pulled back first layer 120c may be formed in a middle portion of the sacrificial material layer 130a. Additionally, the dielectric filling material layer 140a may also be formed to fill the groove formed in the middle portion of the isotropic sacrificial material layer 130a through an isotropic deposition process.

In one embodiment, the isotropic sacrificial material layer 130a may be made of a material having an etch selectivity with respect to a material of each of the second layer 110b and the dielectric filling material layer 140a, and may be made of, for example, silicon nitride. Additionally, the dielectric filling material layer 140a may be made of a material having etch selectivity with respect to a material of each of the second layer 110b and the isotropic sacrificial material layer 130a, and may be made of, for example, silicon oxide.

Referring to FIG. 13, a pullback process may be performed on the isotropic sacrificial material layers 130a exposed through the first opening R1 so that the dielectric filling material layer 140a protrudes from the isotropic sacrificial material layer. In this regard, the pullback process may be performed so that a portion of the isotropic sacrificial material layer 130b remains on a side surface of the first layer 120c. As a result, two grooves separated from each other via the protruding portion of the dielectric filling material layer 140a may be formed on the side surface of the first layer 120c located between the vertically adjacent second layers 110b.

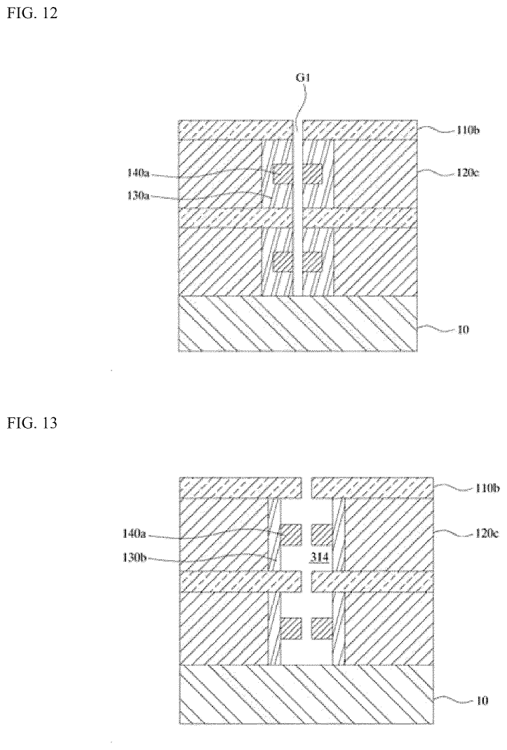

Referring to FIG. 14, a gate insulating layer 150a and a gate electrode 160a may be sequentially formed in each of the two grooves formed on the side surface of the first layer 120c. The gate insulating layer 150a may be formed to have a constant thickness and along a surface of each of the grooves. Thus, an inner space may be defined by the gate insulating layer 150a. The gate electrode 160a may be formed to fill the groove. The gate insulating layer 150a may be made of a dielectric material such as silicon oxide. The gate electrode 160a may be made of a metal material such as tungsten.

In one embodiment, after forming the gate insulating film 150a and the gate electrode 160a, the first opening G1 may be filled with a dielectric filling material 170a through a deposition process.

Referring to FIG. 15a second opening G2 and a third opening G3 may be respectively formed at positions spaced apart from each other while the first opening G1 is disposed therebetween. The second and third openings G2 and G3 may be formed through an anisotropic etching process such as reactive ion etching (RIE).

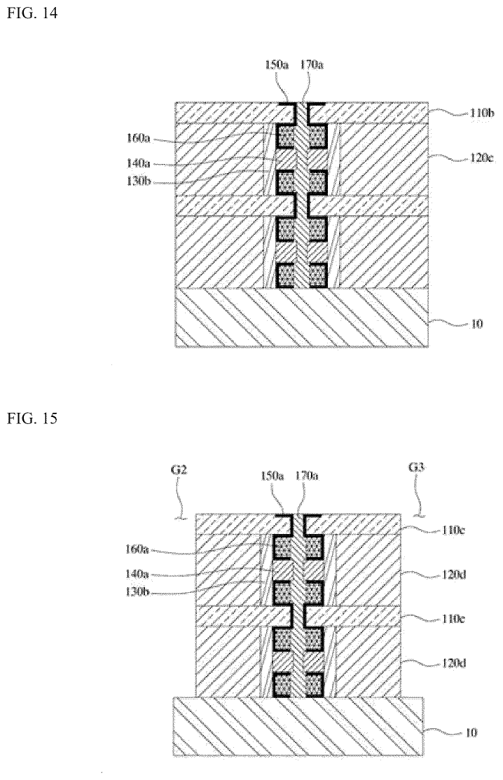

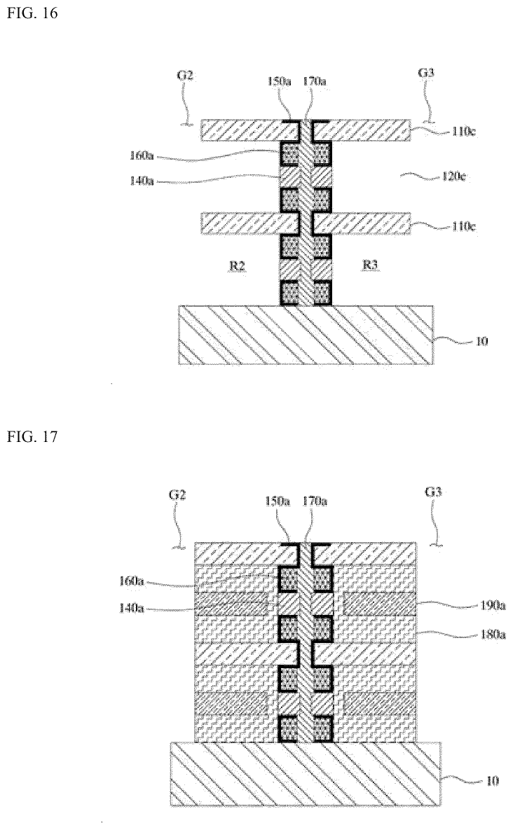

Referring to FIG. 16, a pullback process may be performed on the first layer 120d exposed through the second and third openings G2 and G3, such that a second recess R2 formed inwardly from a side surface of the third opening G2 and a third recess R3 formed inwardly from a side surface of the third opening G3 may be formed in the first layer 120d. In this regard, the pullback process may be performed on the first layer 120d to remove the remaining portion of the isotropic sacrificial material layer 130b.

Referring to FIG. 17, a first dielectric material layer 180a and a second dielectric material layer 190a may be sequentially formed in each of the second recess R2 and the third recess R3. The first dielectric material layer 180a and the second dielectric material layer 190a may be respectively made of dielectric materials not only having an etch selectivity relative to each other and but also having an etch selectivity relative to a material of the second layer 110c. The first dielectric material layer 180a may be formed through an isotropic deposition process such as an atomic layer deposition (ALD) process. In this regard, the first dielectric material layer 180a having a constant thickness may be formed along the surfaces of the adjacent second layers 110c and bottom surfaces of the second and third recesses R2 and R3 located therebetween. As a result, a laterally extending groove may be formed in a middle portion of the first dielectric material layer 180a. Additionally, the second dielectric material layer 190a may also be formed to fill the groove formed in the middle portion of the first dielectric material layer 180a through an isotropic deposition process.

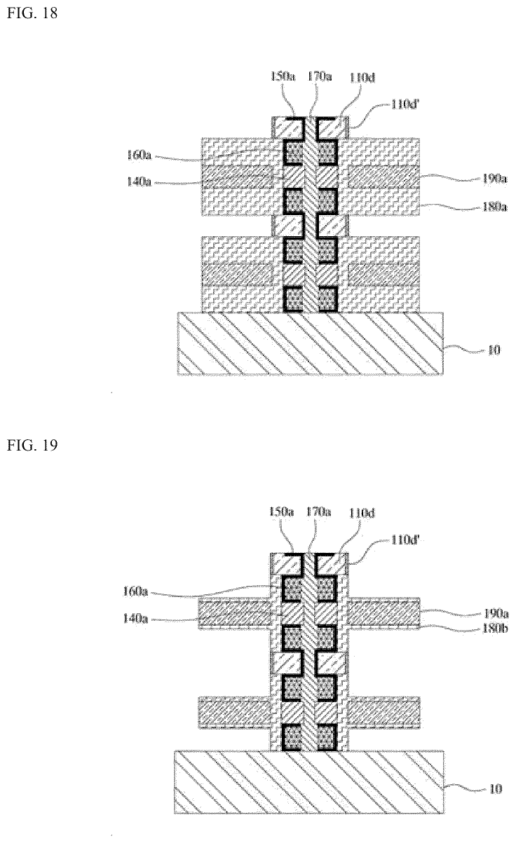

Referring to FIG. 18, a pullback process may be performed on the second layer 110c exposed through the second opening G2 and the third opening G3 such that a portion thereof remains. The pullback process on the second layer 110c may be performed through an etching process using tetramethylammonium hydroxide (TMAH) or an isotropic dry plasma etching process.

After the pullback process, phosphorus (P) may be doped into a side surface of the remaining second layer 110d exposed through the second opening G2 and the third opening G3 to form a source electrode 110d′. The doping of phosphorus (P) into the side surface of the remaining second layer 110d may be performed through a thermal diffusion process using a phosphorus (P) source gas. In one embodiment, phosphine (PH₃) or the like may be used as the phosphorus source gas.

In one embodiment, in a state in which a trace amount of boron and phosphorus has been doped into the second layer 110a in a process of forming the first layer 120a doped with boron and phosphorus, the phosphorus may be doped through a thermal diffusion process using the phosphorus source gas to form the source electrode 110d′. In this case, a process time for forming the source electrode 110d′ via the thermal diffusion doping of phosphorus (P) may be significantly reduced.

Referring to FIG. 19, a selective etching process is performed on the exposed first dielectric material layer 180a in the second recess R2 and the third recess R3 such that a thickness of the first dielectric material layer 180a may be reduced. As a result, the second and third recesses R2 and R3 may be expanded in size.

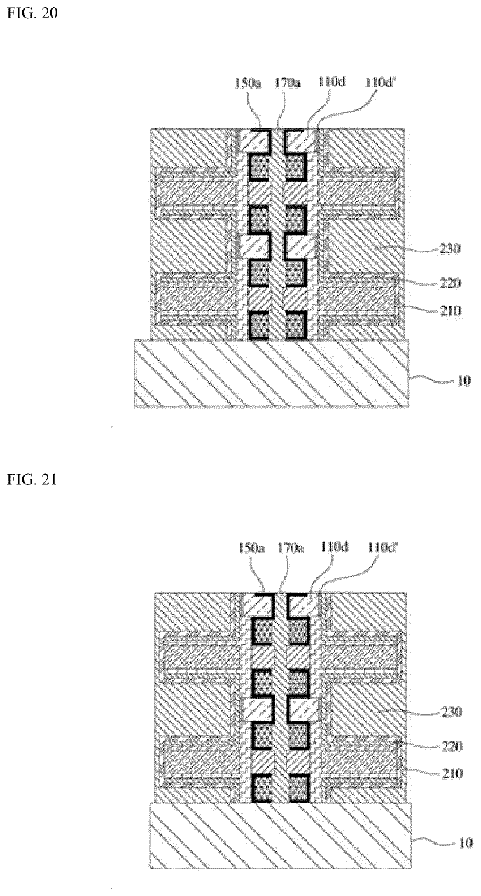

Referring to FIG. 20, the outer electrode layer 210, the dielectric layer 220, and the inner electrode layer 230 may be sequentially formed in each of the second and third recesses R2 an R3. The outer electrode layer 210 and the inner electrode layer 230 may be formed via a deposition process of an electrically conductive material. The dielectric layer 220 may be formed via a deposition process of a dielectric material. For example, the outer electrode layer 210 may be formed to have a constant thickness and on and along a surface defining each of the second and third recesses R2 and R3 through an isotropic deposition process. The dielectric layer 220 may be formed to a certain thickness and on and along an inner groove surface of the outer electrode layer 210 corresponding to the second and third recesses R2 and R3. The inner electrode layer 230 may be formed to fill the inner groove of the dielectric layer 220 corresponding to the third recesses R2 and R3. In this regard, the outer electrode layer 210 may be formed to be electrically connected to the source electrode 110d′.

Referring to FIG. 21, the dielectric filling material 170a filling the inside of the first opening G1 may be etched to expose an end of the remaining second layer 110d. Subsequently, the exposed end of the remaining second layer 110d may be n-doped to form a drain electrode 110d″. Since the n-doping process for forming the drain electrode 110d″ is substantially the same as the n-doping process for forming the source electrode 110d′, a redundant detailed description thereof will be omitted.

Next, a bit-line node 300 to electrically connect the drain electrode 110d″ to the bit-line BL may be formed by filling an inside of an opening formed by etching the dielectric filling material 170a with a conductive material.

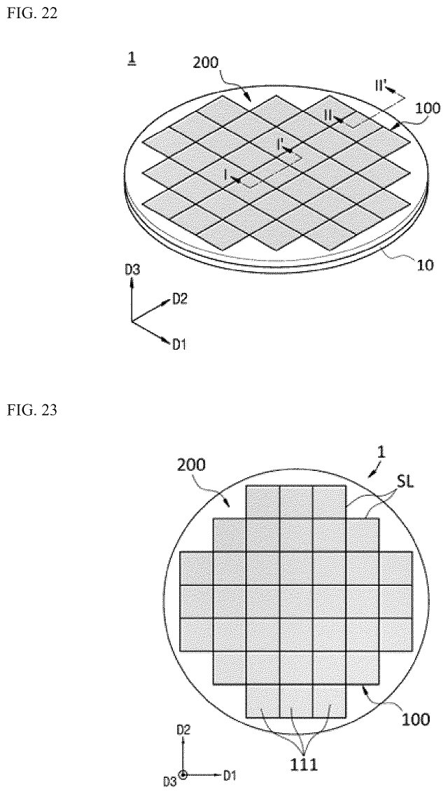

FIG. 22 is a perspective view schematically showing an epitaxial wafer according to the present disclosure, and FIG. 23 is a plan view of FIG. 22. Referring to FIG. 22 and FIG. 23, the epitaxial wafer 1 according to one embodiment of the present disclosure includes the substrate 10; and the stack structure disposed on the substrate 10, wherein the stacked structure includes a first area 100 constituting a semiconductor element and a second area 200 disposed around the first area 100, wherein in the second area 200, silicon (Si) layers and silicon germanium (SiGe) layers are alternately stacked on top of each other.

In this regard, the silicon germanium layer of the second area may include boron (B). A conventional epitaxial wafer has a structure in which a silicon germanium (SiGe) layer and a silicon layer were sequentially stacked on a silicon substrate. The silicon germanium (SiGe) layer and the silicon layer may be formed via epitaxial growth and have different lattice constants. Specifically, the lattice constant of silicon is 5.43 Å, while the lattice constant of germanium is 5.66 Å, so that the silicon germanium layer has a larger lattice constant than that of the silicon layer. Therefore, when the silicon germanium layer is grown epitaxially on the silicon layer, the silicon layer is subjected to a tensile force due to the difference between the lattice constants of the silicon layer and the silicon germanium layer, and as a result, strain may occur. Thus, a misfit dislocation may occur at an interface therebetween. In particular, when a silicon/silicon germanium multilayer thin film is needed to improve the integration, and a total thickness of the silicon germanium layer is large, the above problem may occur more frequently. Thus, there is a limitation in forming the stack structure having an ultra-height.

The present disclosure has been designed to solve this problem, and the inventors of the present disclosure have found that a difference between the lattice constants as described above may be minimized when the silicon germanium (SiGe) layer is doped with boron (B). The epitaxial wafer according to the present disclosure includes the silicon germanium (SiGe) layer containing boron (B). Thus, the difference between the lattice constants of the silicon layer and the silicon germanium (SiGe) layer may be minimized, and an interlayer defect may be minimized even in an ultra-high-rise stacked structure.

In one example of the present disclosure, the silicon germanium (SiGe) layer of the second area of the epitaxial wafer according to the present disclosure may include the compound represented by the Chemical Formula Si_{1-x-y}GeₓB_{y} (0<x≤0.4, 0<y≤0.4). The compound represented by the above Chemical Formula may be a compound in which boron (B) exists in a partially dissolved state in silicon germanium (SiGe). When the epitaxial wafer according to the present disclosure satisfies the above content range, stress may be suppressed by reducing the difference between the lattice constants of the silicon layer and the silicon germanium (SiGe) layer in the second area.

In one example, the average thickness of the silicon (Si) layer and/or silicon germanium (SiGe) layer of the second area of the epitaxial wafer according to the present disclosure may be 100 nm or smaller. FIG. 25 is a cross-sectional view taken along a line II-II′ of FIG. 22, and schematically shows a cross-section of the second area of the epitaxial wafer according to this example. Referring to FIG. 25, an average thickness t21 of the silicon layer 210 of the second area 200 of the epitaxial wafer 1 according to the present disclosure may be 100 nm or smaller, and an average thickness t22 of the germanium layer 220 of the second area 200 may be 100 nm or smaller. Alternatively, each of the average thickness t21 of the silicon layer 210 and the average thickness t22 of the silicon germanium layer 220 in the second area 200 may be 100 nm or smaller. As described above, in the epitaxial wafer 1 according to the present disclosure, the silicon germanium layer 220 of the second area 200 may be doped with boron to reduce the difference between the lattice constants of the silicon layer 210 and the silicon germanium layer 220. Thus, the stress between the silicon layer 210 and the silicon germanium layer 220 may be minimized. Accordingly, each of the silicon layer 210 and/or the silicon germanium layer 220 of the second area 200 may have an average thickness of 100 nm or smaller. A lower limit of the average thickness of each of the silicon layer and/or the silicon germanium layer is not particularly limited, but may be, for example, greater than 0 nm.

In one embodiment of the present disclosure, the number of stacks in the second area of the silicon epitaxial wafer according to the present disclosure may be 3 or larger. The number of stacks in the second area being 3 or greater means that the number of stacks of silicon layers included in the second area is 3 or greater, the number of stacks of silicon germanium layers included in the second area is 3 or greater, or the number of stacks of the silicon layer and the silicon germanium layer included in the second area is 3 or greater. An upper limit of the number of the stacks in the second area is not particularly limited, but may be, for example, 1000 or smaller. The silicon epitaxial wafer according to this embodiment may have the number of stacks as described above, thereby realizing high capacity.

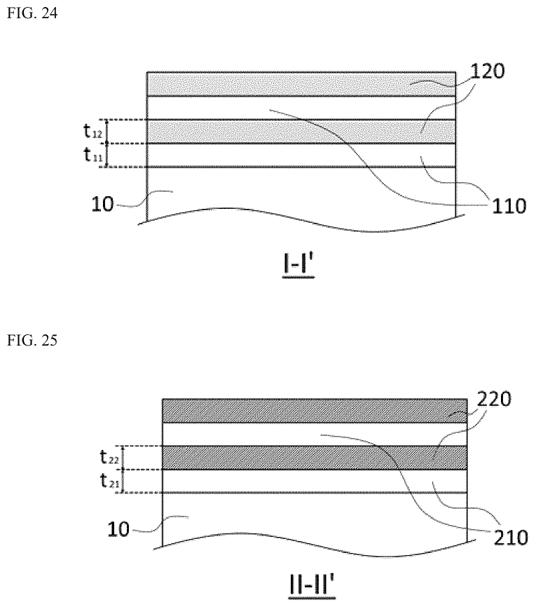

The epitaxial wafer according to the present disclosure may include the first area constituting a semiconductor element. In this regard, the first area may include the stack in which the (Si) layers and the insulating layers are alternately stacked on top of each other. FIG. 24 is a cross-sectional view schematically showing the first area 100 of the epitaxial wafer 1 according to the present disclosure. Referring to FIG. 24, the first area 100 of the epitaxial wafer 1 according to the present disclosure may include a structure in which the silicon layers 110 and the insulating layers 120 are alternately stacked on top of each other. The insulating layer 120 may be formed by etching and removing the silicon germanium layer disposed between the silicon layers, as described later.

In one example, the insulating layer of the first area of the epitaxial wafer according to the present disclosure may be embodied as an empty space. The insulating layer as the empty space may be used in ta process for manufacturing a semiconductor device using an epitaxial wafer according to the present disclosure. More specifically, a mask pattern with an etch selectivity may be formed on the first area and an etching process of at least a portion of the first area using the mask pattern may be performed multiple times, thereby forming the insulating layer as the empty space. That is, the empty space may be a space remaining after the silicon germanium layer in the first area is etched and removed.

In one example, the insulating layer of the first area of the epitaxial wafer according to the present disclosure may include a different component than that of the silicon germanium layer of the second area. For example, the insulating layer may include at least one selected from a group consisting of silicon oxide, silicon nitride, and silicon oxynitride. The insulating layer may be formed in the above-mentioned empty space or may fill the empty space.

In one embodiment of the present disclosure, the first area of the epitaxial wafer according to the present disclosure may include a plurality of unit elements that are repeatedly arranged in a direction perpendicular to the stacking direction of the layers of the stack structure. In this regard, the plurality of unit elements may be arranged so as to be spaced apart from each other via the scribe line. Referring to FIG. 23, the first area 100 of the epitaxial wafer 1 according to the present embodiment may include a plurality of unit elements 111 distinguished from each other via the scribe line SL. The wafer may be cut into individual chips based on the scribe line SL during the dicing process on the wafer.

The scribe line SL may be formed in a grid shape. For example, the scribe line SL may include a horizontal line extending along the first direction D1 and a vertical line extending along the second direction D2 intersecting the first direction D1. In FIG. 23, it is shown that a length in the first direction D1 of the unit element and a length in the second direction D2 thereof are equal to each other. However, the present disclosure is not limited thereto. The length in the first direction D1 of the unit element and the length in the second direction D2 thereof are different from each other.

In an example of the present disclosure, each of the plurality of unit elements included in the first area of the epitaxial wafer according to the present disclosure may include a cell area CELL including a memory cell array and a circuit area (PERI; peripheral circuit area) controlling the memory cell array.

In the above example, the unit element included in the first area may include a plurality of word-lines, a plurality of memory cell transistors connected to each word-line, and a plurality of bit-lines connected to the memory cell transistor. This structure may be a structure in which one memory cell transistor is disposed between one word-line and one bit-line. A gate of the memory cell transistor may be connected to the word-line, and a source of the memory cell transistor may be connected to the bit-line. Each memory cell may include a capacitor. The word-line, the memory cell transistor, the bit-line, and the capacitor may constitute one cell, and one unit element may include a plurality of cells.

In one embodiment of the present disclosure, at least two or more of the plurality of memory cell transistors included in each of the plurality of unit elements disposed in the first area of the epitaxial wafer may be arranged in the stacking direction of the layers in the stack structure. This structure may be a structure in which the plurality of memory cell transistors within the unit element are stacked and arranged in a third direction D3. That is, the unit element included in the first area of the epitaxial wafer according to the above example may be a three-dimensional semiconductor memory element. An epitaxial wafer according to the present disclosure may have a structure in which the silicon layers and the boron-doped silicon germanium layers are stacked alternately on top of each other. As described above, the interlayer dislocation may be prevented by reducing the stress between the silicon layer and the silicon germanium layer via the introduction of the boron-doped silicon germanium layer. Thus, the memory element in which the defect is suppressed while allowing the high-rise stack structure to be implemented may be realized.

In one embodiment, the plurality of word-lines included in the unit element of the epitaxial wafer according to the present disclosure may extend in a perpendicular manner to the substrate. Within one unit element, the plurality of word-lines may be arranged to be spaced apart from each other in a first direction D1 or a second direction D2. When the plurality of word-lines extend in a perpendicular manner to the substrate, the plurality of bit-lines included in the unit element may extend in a parallel manner to an upper surface of the substrate 110 or 210, and may be arranged and spaced from each other in the third direction 3D.

In another embodiment, the plurality of bit-lines included in the unit element of the epitaxial wafer according to the present disclosure may extend in a perpendicular manner to the substrate. Within one unit element, the plurality of bit-lines may be arranged to be spaced apart from each other in the first direction D1 or the second direction D2. When the plurality of bit-lines extend in a perpendicular manner to the substrate, the plurality of word-lines included in the unit element may extend in a parallel manner to the upper surface of the substrate, and may be arranged and spaced from each other in the third direction 3D.

In still another embodiment, the plurality of word-lines and the plurality of bit-lines included in the unit element of the epitaxial wafer according to the present disclosure may extend in a perpendicular manner to the substrate. Within one unit element, the plurality of word-lines and the plurality of bit-lines may be arranged to be spaced apart from each other in the first direction D1 or the second direction D2.

The word-line and/or bit-line may be embodied as a conductive pattern and may have a line shape or a bar shape. The word-line and/or the bit-line may include one selected from a conductive material, for example, doped semiconductor material (doped silicon, doped germanium, etc.), conductive metal nitride (titanium nitride, tantalum nitride, etc.), metal (tungsten, titanium, tantalum, etc.), and a metal-semiconductor compound (tungsten silicide, cobalt silicide, titanium silicide, etc.). However, embodiments of the present disclosure are not limited thereto.

The present disclosure also relates to a method for manufacturing the epitaxial wafer.

A method for manufacturing an epitaxial wafer according to the present disclosure includes alternately growing the silicon layers and the silicon germanium layers on top of each other on the substrate, wherein the silicon germanium layer may contain doped boron (B). The silicon layers and the silicon germanium layers may be grown alternately on top of each other to form the stack structure including the silicon layers and the silicon germanium layers on the substrate.

The stack structure may include an additional insulating film disposed on the uppermost silicon layer or silicon germanium layer, if necessary.

After forming the stack structure, a patterning process may be performed thereon. The patterning process may include forming a mask pattern having openings defined therein, etching the stack structure using the mask pattern as an etch mask, and removing the mask pattern. Through the patterning process, a trench may be formed on the substrate, and a portion of the upper surface of the substrate may be exposed through the trench. Afterwards, a process of forming a new insulating film in the trench may be performed. The new insulating film may have an etch selectivity.

The patterning process may be performed multiple times based on a target structure of the semiconductor device. When performing the patterning process multiple times, at least a portion of the insulating film formed in the previous step may be etched and then the new insulating film may be performed. The first area of the epitaxial wafer according to the present disclosure may refer to the unit element after performing the patterning process, and may have a stack structure of the silicon layers not removed in the patterning process and the insulating films newly formed after the silicon germanium layer has been removed by the etching.

Additionally, in the patterning process, an area located outside the mask pattern may be the second area. The second area may include a stack structure formed by alternately growing the silicon layer and the silicon germanium layers on top of each other, wherein the silicon germanium layer may contain boron (B) as described above.

After performing the patterning process, if necessary, an impurity doping process may be performed on a portion of the semiconductor exposed by the etching. The impurity may be a p-type impurity or an n-type impurity. The p-type impurities may include B, BF, or a combination thereof, and the n-type impurities may include P, As, or a combination thereof.

Additionally, after performing the patterning process, if necessary, a process of converting the portion of the semiconductor exposed by the etching into the conductive material may be performed. The process of converting the semiconductor into the conductive material may include, for example, a silicide process. The exposed portion of the semiconductor may react with a metal to form a metal-semiconductor compound (tungsten silicide, cobalt silicide, titanium silicide, etc.). In another example, converting the semiconductor into the conductive material may include conformally forming a metal nitride film or metal film on the semiconductor.

After performing the patterning process, etc., if necessary, a process of filling the empty space of the remaining trench with the insulating film may be performed. The insulating film may include one of a silicon oxide film, a silicon nitride film, and a silicon oxynitride film.

The present disclosure is described below in more detail based on Present Examples and Comparative Examples. However, the idea of the present disclosure is not limited to Examples as described later.

### Changes in Bond Length and Lattice Constant of Silicon Due to Impurity Doping

The structure and elastic properties of boron-doped silicon were calculated in a following manner. First, a simulation of a supercell structure with 64 atoms was performed using DFT (density functional) to calculate a theoretical value. In a simulation scheme, using the Vienna ab initio simulation package (VASP) tool, changes in the bond length and the lattice constant of silicon when the dopant was doped at 0, 6.25, 12.5, and 18.75% into silicon atoms were identified. In the simulation, a convergence value of the kinetic cutoff energy was set to 450 eV, and the supercell was calculated using 5×5×5 Monkhorst-Packgrid.

TABLE 1

| | | Si-Si | Si-X (X = B, Al, Ga) |
|---|---|---|---|
| Material | atom % | (Å) | (Å) |
| Si:B | 0 | 2.339 | n/a |
| | 6.25 | 2.335 | 2.048 (n: 16) |
| | 12.5 | 2.336 | 2.028 (n: 32) |
| | 18.75 | 2.34 | 2.015 (n: 48) |
| Si:Al | 0 | 2.339 | n/a |
| | 6.25 | 2.343 | 2.426 (n: 16) |
| | 12.5 | 2.341 | 2.443 (n: 32) |
| | 18.75 | 2.339 | 2.45 (n: 48) |
| Si:Ga | 0 | 2.339 | n/a |
| | 6.25 | 2.341 | 2.378 (n: 16) |
| | 12.5 | 2.339 | 2.39 (n: 32) |
| | 18.75 | 2.337 | 2.397 (n: 48) |

Table 1 above shows the bond length based on a doping concentration when Si is doped with each of B, Al, and Ga belonging to group IIIA. As shown in Table 1, as the content of each doped element increases from 6.25 at % to 18.75 at %, the number of doped elements binding to Si increases from 0 to 48, and accordingly, the number of Si—Si bonds decreases from 128 to 80.

Further, referring to Table 1, it may be identified that when doping B atoms, the bond length of Si—B decreases as the concentration of B increases. On the other hand, it may be identified that when the concentration of each of Al and Ga increases, the bond length of each of Si—Al and Si—Ga increases. Through the above results, it may be identified that the bond length may be reduced when boron is doped into the crystal structure of Si.

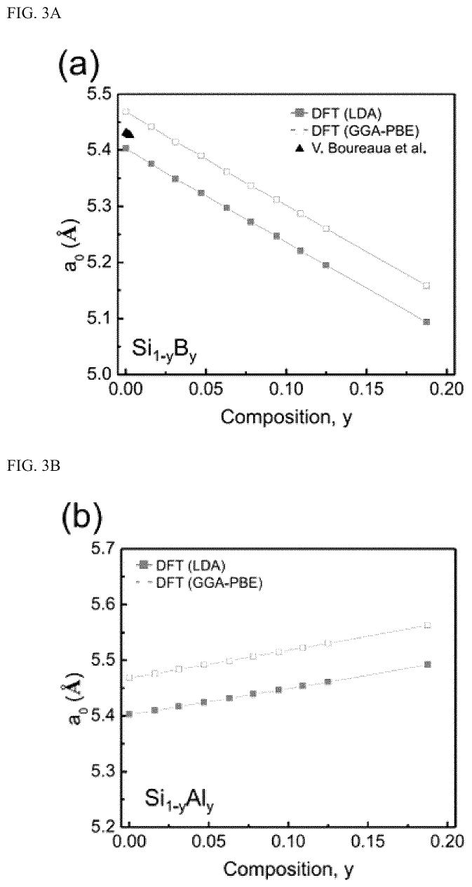

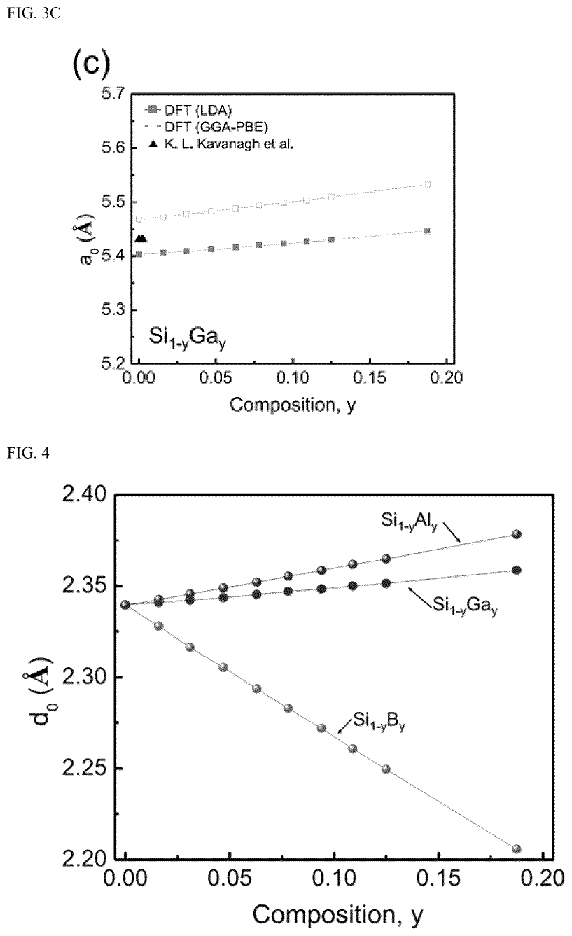

FIGS. 3A to 3C shows a relaxed lattice constant of each of (FIG. 3A) Si_{1-y}B_{y}, (FIG. 3B) Si_{1-y}Al_{y}, and (FIG. 3C) Si_{1-y}Ga_{y} as calculated using LDA and GGA-PBE.

Referring to FIGS. 3A to 3C, it may be identified that the relaxed lattice constant decreases as the doping concentration of B belonging to the same group IIIA increases, whereas the relaxed lattice constant increases as the doping concentration of each of Al and Ga belonging to the same group IIIA increases.

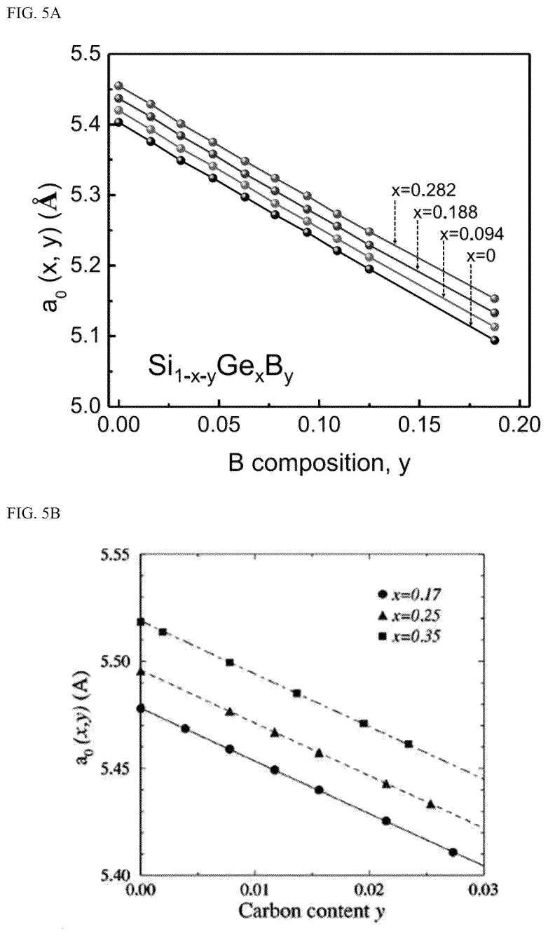

FIG. 4 is a graph showing an average bond length based on the doping concentration of each of Si_{1-y}B_{y}, Si_{1-y}Al_{y}, and Si_{1-y}Ga_{y}.

Referring to FIG. 4, as may be inferred from the change in the lattice constant as described above, it may be identified that the average bond length decreases as the doping concentration of B increases, whereas the average bond length increases as the doping concentration of each of Al and Ga increases.

### Effect of Doping on Silicon Germanium

Si and Ge have lattice constants of 5.43 Å and 5.66 Å, respectively. SiGe generally has a lattice constant that is linearly proportional in a range between the above values depending on a proportion of germanium contained in silicon. Therefore, when the silicon layer and the silicon germanium layer are sequentially epitaxially grown on top of each other, a mismatch between the lattice constant of the silicon layer and the lattice constant of the silicon germanium layer occurs because the lattice constant of the silicon germanium layer is larger than that of the lattice constant of the silicon layer.

FIG. 5A is a graph showing the calculation of the lattice constant based on a change in a concentration of B in Si_{1-x-y}GeₓB_{y}, and FIG. 5B is a graph showing the calculation of the lattice constant based on a change in a concentration of C in Si_{1-x-y}GeₓC_{y}. x denotes a fraction of Ge, and y denotes a fraction of B or C. When y is 0, the graph value represents the lattice constant of silicon germanium not doped with B and C.

Referring to FIG. 5A, it may be identified that the lattice constant of Si_{1-x-y}GeₓB_{y} decreases as y increases. The value of y is changed such that the lattice constant of Si_{1-x-y}GeₓB_{y} is adjusted to be 5.43 Å as the lattice constant of silicon. In addition, it may be identified that even though the fraction of Ge increases, the fraction of B may be controlled such that the lattice constant of Si_{1-x-y}GeₓB_{y} matches that of silicon. Specifically, it may be identified that in Si_{1-x-y}GeₓB_{y}, the strain caused by doping of 8.4 atomic % of germanium (Ge) may be canceled by doping of about 1 atomic % of boron (B). Accordingly, it is preferred that in the boron doped silicon germanium layer, a ratio (y/x) of y to x is in a range of about 0.06 to 0.15.

Referring to FIG. 5B, it may be identified that the lattice constant of Si_{1-x-y}GeₓC_{y} decreases as y increases. The value of y may be changed such that the lattice constant of Si_{1-x-y}GeₓC_{y} may be adjusted to be 5.43 Å as the lattice constant of silicon. In addition, it may be identified that even though the fraction of Ge increases, the fraction of C may be controlled such that the lattice constant of Si_{1-x-y}GeₓC_{y} matches that of silicon.

Through the above results, it may be identified that when the silicon germanium layer contains boron or carbon, the difference between the lattice constants of the silicon layer and the silicon germanium layer may be reduced. Therefore, the epitaxial wafer according to the present disclosure minimizes the difference between the lattice constant of the silicon layer and the silicon germanium layer, such that the stress that may occur between the silicon layer and the silicon germanium layer may be minimized. Further, even in a structure in which layers with different components are stacked, the occurrence of defects may be prevented by suppressing the occurrence of mismatches or dislocations between crystal lattice atoms.

Through the above results, it may be identified that when the silicon germanium layer contains boron, the difference between the lattice constants of the silicon layer and the silicon germanium layer may be reduced. Therefore, the epitaxial wafer according to the present disclosure minimizes the difference between the lattice constant of the silicon layer and the silicon germanium layer, such that the stress that may occur between the silicon layer and the silicon germanium layer may be minimized. Further, even in a structure in which layers with different components are stacked, the occurrence of defects may be prevented by suppressing the occurrence of mismatches or dislocations between crystal lattice atoms.

### Effect of Boron Doping on Epitaxial Single Structure

### Comparative Example

An epitaxial wafer with a single undoped Si₁₋ₓGeₓ layer (approximately x=21 atomic %) on the substrate was manufactured.

### Present Example

An epitaxial wafer (B₂H₆ flow rates 50, 110, and 150 sccm) of the B-doped Si₁₋ₓGeₓ layer (approximately x=21 atomic %) on the substrate was manufactured.

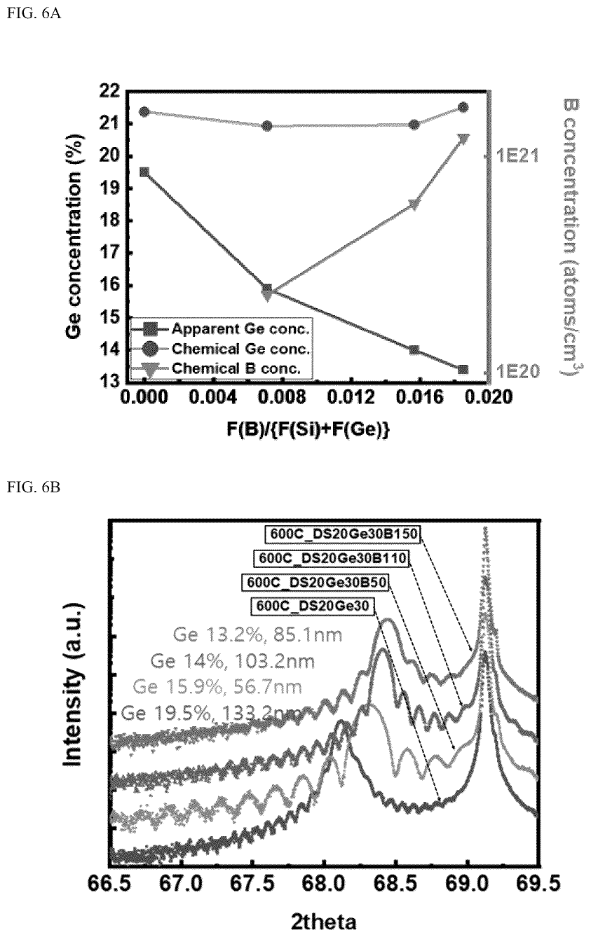

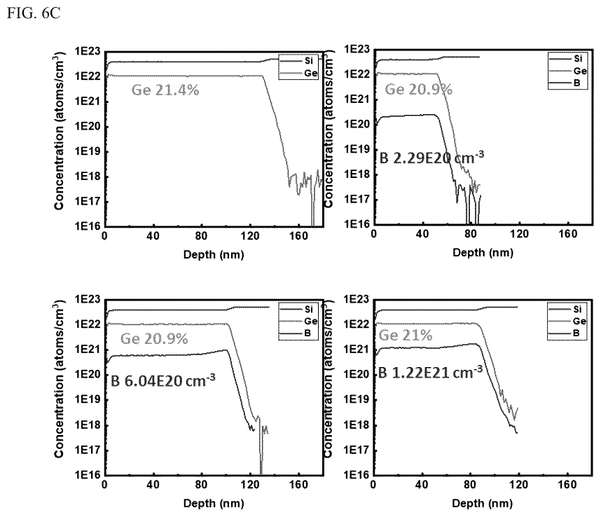

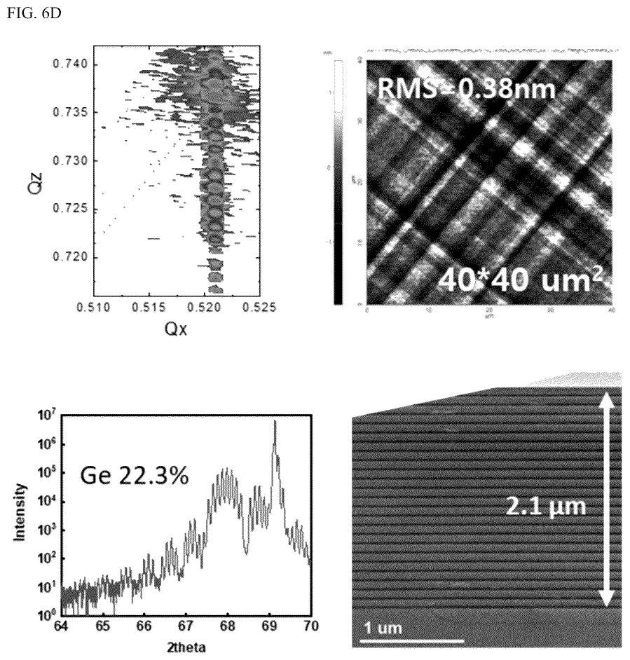

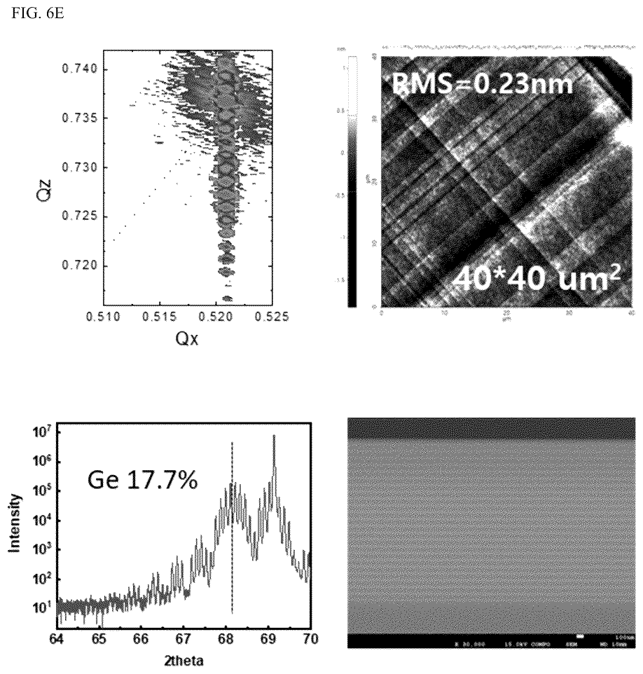

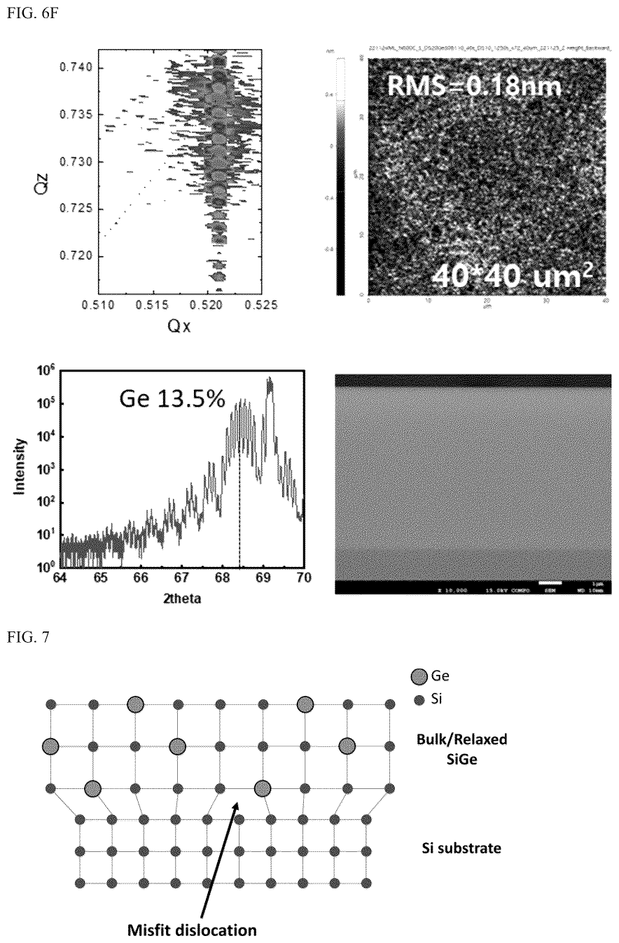

FIGS. 6A to 6C are diagrams showing the Ge and B compositions and strain and defect analysis results measured on the epitaxial wafer according to the Comparative Example and Present Example, respectively.

Referring to FIG. 6A, the chemical Ge concentration was maintained during B doping, but the apparent Ge concentration decreased as the B concentration increased. FIG. 6B shows the HR-XRD measurement results based on the apparent Ge concentration in FIG. 6A, and FIG. 6C shows the SIMS measurement results based on the chemical Ge and B concentrations in FIG. 6A.

### Effect of Boron Doping on Epitaxial Multilayer Stack Structure

### Comparative Example 1

An epitaxial wafer was manufactured by stacking 24 pairs of 20 nm thick Si₁₋ₓGeₓ layers (x=23 atomic %) and 70 nm thick Si layers alternately on top of each other on the substrate.

### Comparative Example 2

An epitaxial wafer was manufactured by stacking 24 pairs of 20 nm thick Si₁₋ₓGeₓ layers (x=19 atomic %) and 70 nm thick Si layers alternately on top of each other on the substrate.

### Present Example

An epitaxial wafer was manufactured by stacking 72 pairs of 20 nm thick B-doped Si₁₋ₓGeₓ layers (x=19 atomic %) and 70 nm thick Si layers alternately on top of each other on the substrate.

FIG. 6D to FIG. 6F are diagrams showing the strain and defect analysis results measured on the epitaxial wafers according to Comparative Examples 1 and 2 and Present Example, respectively.

Referring to FIG. 6D and FIG. 6E, it may be identified that in Comparative Examples 1 and 2, as the content of germanium in the Si₁₋ₓGeₓ layer increases, the density of defects formed inside and on the surface of the stack structure increases due to the increase in lattice mismatch.

Referring to FIG. 6E and FIG. 6F, it may be identified that when the Si₁₋ₓGeₓ layer is doped with boron (B), the apparent Ge concentration of the Si₁₋ₓGeₓ layer decreases, resulting in a higher number of stacks of the Si₁₋ₓGeₓ layers and the Si layers than that when the boron is not doped. Thus, in a stack structure in which first and second layers having different Ge concentrations are alternately stacked on top of each o there, when boron is doped in the layer having a relatively higher Ge concentration among the first and second layers, the stress caused inside the stack structure may be lowered. As a result, it is fully predicted that the stack structure including a larger number of layers can be formed.

Although embodiments of the present disclosure have been described with reference to the accompanying drawings, embodiments of the present disclosure are not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. An epitaxial wafer comprising:
a substrate; and
a stack structure disposed on the substrate, wherein the stack structure includes first and second layers alternately stacked on top of each other,
wherein the first layer is made of a compound represented by one selected from a group consisting of following Chemical Formulas 1-1 to 1-5,
wherein the second layer is made of a compound represented by a following Chemical Formula 2:
Si₁₋ₓGeₓ(m≤x≤1.0) [Chemical Formula 1-1]
Si_{1-x-y}GeₓB_{y}(m≤x<1.0,0<y≤0.4,0.2<x+y≤1.0) [Chemical Formula 1-2]
Si_{1-x-z}GeₓP_{z}(m≤x<1.0,0<z≤0.4,0.2<x+z≤1.0) [Chemical Formula 1-3]
Si_{1-x-z}GeₓC_{z}(m≤x<1.0,0<z≤0.4,0.2<x+z≤1.0) [Chemical Formula 1-4]
Si_{1-x-y-z}GeₓB_{y}P_{z}(0.2<x<1.0,0<y≤0.4,0<z≤0.4,0.2<x+y+z≤1.0) [Chemical Formula 1-5]
Si₁₋ₐGeₐ(0<a≤m) [Chemical Formula 2]
where in each of the Chemical Formulas 1-1 to 1-5 and the Chemical Formula 2, m is a real number in a range of 0 inclusive to 1 inclusive, and x-a is equal to or larger than 0.2.

2. The epitaxial wafer of claim 1, wherein the first layer is made of a compound represented by one selected from a group consisting of the Chemical Formulas 1-2 to 1-5.

3. The epitaxial wafer of claim 1, wherein an average thickness of each of the first layer and the second layer is in a range of 0 nm exclusive to 200 nm inclusive.

4. The epitaxial wafer of claim 1, wherein the stack structure further includes a third layer disposed between the first layer and the second layer, wherein the third layers acts as a diffusion barrier against diffusion of germanium (Ge).

5. The epitaxial wafer of claim 4, wherein the third layer is made of silicon (Si) doped with arsenic (As) or stibium (Sb).

6. The epitaxial wafer of claim 5, wherein a concentration of arsenic (As) or stibium (Sb) in the third layer is in a range of 0.05 to 10 atomic %.

7. The epitaxial wafer of claim 1, wherein the epitaxial wafer further comprises a buffer layer disposed between the substrate and the stack structure, wherein the buffer layer is made of silicon (Si) doped with germanium (Ge) at a higher doping concentration than a doping concentration at which the first layer is doped with germanium (Ge).

8. The epitaxial wafer of claim 7, wherein the germanium concentration in the buffer layer is in a range of 0.01 to 20 atomic %.

9. A method for manufacturing a semiconductor device, the method comprising:
forming a stack structure on a substrate by alternately stacking first and second layers on top of each other on the substrate;
forming a first opening exposing at least one first side surface of each of the first and second layers of the stack structure;
doping phosphorus (P) into the first side surface of the second layer exposed through the first opening via a thermal diffusion process using a phosphorus (P) source gas, thereby forming a first electrode;
forming a second opening exposing at least one second side surface of each of the first and second layers at a position spaced apart from the first opening;
selectively etching the at least one second layer within the second opening to form a semiconductor pattern such that the first electrode is formed on a side surface of the semiconductor pattern; and
doping phosphorus (P) into the side surface of the semiconductor pattern exposed through the second opening via a thermal diffusion process using a phosphorus (P) source gas, thereby forming a second electrode,
wherein a portion of the second layer remaining between the first electrode and the second electrode functions as a semiconductor channel,
wherein the first layer is made of a compound represented by one selected from a group consisting of following Chemical Formulas 1-1 to 1-5,
wherein the second layer is made of a compound represented by a following Chemical Formula 2:
Si₁₋ₓGeₓ(m≤x≤1.0) [Chemical Formula 1-1]
Si_{1-x-y}GeₓB_{y}(m≤x<1.0,0<y≤0.4,0.2<x+y≤1.0) [Chemical Formula 1-2]
Si_{1-x-z}GeₓP_{z}(m≤x<1.0,0<z≤0.4,0.2<x+z≤1.0) [Chemical Formula 1-3]
Si_{1-x-z}GeₓC_{z}(m≤x<1.0,0<z≤0.4,0.2<x+z≤1.0) [Chemical Formula 1-4]
Si_{1-x-y-z}GeₓB_{y}P_{z}(0.2<x<1.0,0<y≤0.4,0<z≤0.4,0.2<x+y+z≤1.0) [Chemical Formula 1-5]
Si₁₋ₐGeₐ(0<a≤m) [Chemical Formula 2]
where in each of the Chemical Formulas 1-1 to 1-5 and the Chemical Formula 2, m is a real number in a range of 0 inclusive to 1 inclusive, and x-a is equal to or larger than 0.2.
